(19) United States
(12) Patent Application Publication
(10) Pub. No.: US 2026/0026111 A1
(43) Pub. Date: Jan. 22, 2026

(54) NARROWBAND LIGHT ABSORPTION DEVICE BASED ON PHASE CHANGE MATERIAL

(71) Applicant: Huazhong University of Science and Technology, Wuhan (CN)

(72) Inventors: Hao TONG, Wuhan (CN); QingShan TAN, Wuhan (CN); QiPei ZHOU, Wuhan (CN); Zhang LE, Wuhan (CN); RuiHan LIU, Wuhan (CN); Xiangshui MIAO, Wuhan (CN)

(73) Assignee: Huazhong University of Science and Technology, Wuhan (CN)

(21) Appl. No.: 19/272,547

(22) Filed: Jul. 17, 2025

(30) Foreign Application Priority Data
Jul. 17, 2024 (CN) 202410960753.0

(51) Int. Cl. H10F 30/10; H10F 77/166; H10N 15/10; H10N 70/00

(52) U.S. Cl. CPC H10F 30/15; H10F 77/166; H10N 15/15; H10N 70/8836

(57) ABSTRACT

A narrowband light absorption device based on a phase change material includes: a narrowband light absorption cavity structure, including a metal layer, a dielectric layer, and a phase change layer; and a lithium tantalate single-crystal wafer structure, disposed below the narrowband light absorption cavity structure. When light irradiates the narrowband light absorption cavity structure, the narrowband light absorption cavity structure is configured to absorb light of a corresponding wavelength to produce a pyroelectric effect, and the lithium tantalate single-crystal wafer structure is configured to generate current so as to obtain light intensity information of the light and change a state of the phase change layer to control an on-off state of the switch. The present disclosure achieves dynamic switching control, and features a very narrow full width at half maximum (FWHM), insensitivity to incident light angle variations, a simple structure, easy integration, and a high switching ratio.

### CROSS-REFERENCE TO RELATED APPLICATIONS

The application claims priority to Chinese patent application No. 202410960753.0, filed on Jul. 17, 2024, the entire contents of which are incorporated herein by reference.

### TECHNICAL FIELD

The present disclosure relates to the technical field of phase change materials, and in particular to a narrowband light absorption device based on a phase change material.

### BACKGROUND

In recent years, many different types of plasmonic refractive index sensors operating in the infrared and terahertz bands have emerged, including hybrid microcavities, nanodisks, network-type metasurfaces, metal gratings, or narrowband light absorption cavity structures composed of other media and metal structures. However, expensive and hard-to-scale fine nanofabrication technology is required for manufacturing of these devices, but the devices lack flexibility in design and have the defect that once the device is formed, the absorbed waveband cannot be dynamically regulated, which results in complexity of the device structure, and inability to use a single device for multi-band regulation.

The narrowband light absorption cavity structures in the prior art mainly include metal/dielectric/metal structures, structures combining metals and dielectrics, or metasurfaces composed of dielectrics/metals, which are structurally complex and sensitive to incident light angle variations. Most metal/dielectric/metal structures are susceptible to structural influences, that is, their colors change with variations in polarization and incident angles. Alternatively, the structures combining metals and dielectrics cannot achieve dynamic switching combination or detect the light intensity. Therefore, it is of great practical significance to design a narrowband light absorption technology with dynamic adjustability.

### SUMMARY

The present disclosure provides a narrowband light absorption device based on a phase change material, with an aim to overcome the defects of narrowband light absorption devices in the prior art including inability to achieve dynamic regulation, and to realize the dynamic regulation of the narrowband light absorption device.

A narrowband light absorption device based on a phase change material provided in the present disclosure includes:
a narrowband light absorption cavity structure, comprising a metal layer, a dielectric layer, and a phase change layer;
a lithium tantalate single-crystal wafer structure, disposed below the narrowband light absorption cavity structure; and
when light irradiates the narrowband light absorption cavity structure, the narrowband light absorption cavity structure is configured to absorb light of a corresponding wavelength to produce a pyroelectric effect, and the lithium tantalate single-crystal wafer structure is configured to generate current so as to obtain light intensity information of the light according to a magnitude of the current, and change a state of the phase change layer according to the magnitude of the current to control an on-off state of the switch.

According to the narrowband light absorption device based on a phase change material provided in the present disclosure, the narrowband light absorption cavity structure includes a first metal layer, a first dielectric layer, a phase change layer, a second dielectric layer, a second metal layer, and a third dielectric layer arranged sequentially from bottom to top.

According to the narrowband light absorption device based on a phase change material provided in the present disclosure, the voltage applied to the first metal layer is regulated according to the magnitude of the current to control a crystallization-amorphization ratio of the phase change material in the phase change layer so as to regulate the absorption of the light.

According to the narrowband light absorption device based on a phase change material provided in the present disclosure, the phase change material of the phase change layer used has an optical loss greater than a first preset threshold, and a refractive index less than a second preset threshold; and
the reflectance of the metal layer is greater than a third preset threshold.

According to the narrowband light absorption device based on a phase change material provided in the present disclosure, the phase change material of the phase change layer used has a thickness of less than 1 μm.

According to the narrowband light absorption device based on a phase change material provided in the present disclosure, a plurality of the phase change layers are arranged, and each of the phase change layers includes a phase change material layer and electrode layers disposed on both sides of the phase change material layer.

According to the narrowband light absorption device based on a phase change material provided in the present disclosure, the electrode layer between two adjacent phase change material layers is shared.

According to the narrowband light absorption device based on a phase change material provided in the present disclosure, a reflective layer is further arranged between the first metal layer and the first dielectric layer.

According to the narrowband light absorption device based on a phase change material provided in the present disclosure, the first metal layer is made of tungsten (W), the reflective layer is made of silver (Ag), the first dielectric layer is made of titanium dioxide (TiO₂), the phase change layer is made of GSST, the second dielectric layer is made of TiO₂, the second metal layer is made of Ag, and the third dielectric layer is made of magnesium fluoride (MgF₂).

According to the narrowband light absorption device based on a phase change material provided in the present disclosure, the first metal layer has a thickness of 200 nm, the reflective layer has a thickness of 200 nm, the first dielectric layer has a thickness of 78 nm, the phase change layer has a thickness of 100 nm, the second dielectric layer has a thickness of 78 nm, the second metal layer has a thickness of 22 nm, the third dielectric layer has a thickness of 22 nm, and the lithium tantalate single-crystal wafer structure has a thickness of 75 μm.

According to the narrowband light absorption device based on a phase change material provided in the present disclosure, the narrowband light absorption cavity structure absorbs a corresponding wavelength, and due to the pyroelectric effect, the lithium tantalate single-crystal wafer structure generates current, the light intensity information is obtained according to the magnitude of the current, to monitor the light intensity; and the state of the phase change layer is changed according to the magnitude of the current, the target light absorption ratio is adjusted, dynamic switching control is achieved, and the narrowband light absorption cavity structure features a very narrow full width at half maximum (FWHM), insensitivity to incident light angle variations, a simple structure, easy integration, and a high switching ratio.

### BRIEF DESCRIPTION OF THE DRAWINGS

In order to more clearly describe the technical solutions in the present disclosure or in the prior art, a brief introduction to the accompanying drawings required for the description of the examples or the prior art will be made below. Apparently, the accompanying drawings in the following description are some examples of the present disclosure, and those of ordinary skill in the art would also be able to derive other drawings from these drawings without making creative efforts.

FIG. 1 is a schematic structural diagram of a narrowband light absorption device based on a phase change material provided by the present disclosure.

FIG. 2 is a schematic diagram of an absorption spectrum of a narrowband light absorption device based on a phase change material provided by the present disclosure.

FIG. 3 is a schematic diagram of a curve showing change of current detected by a narrowband light absorption device based on a phase change material provided by the present disclosure over time.

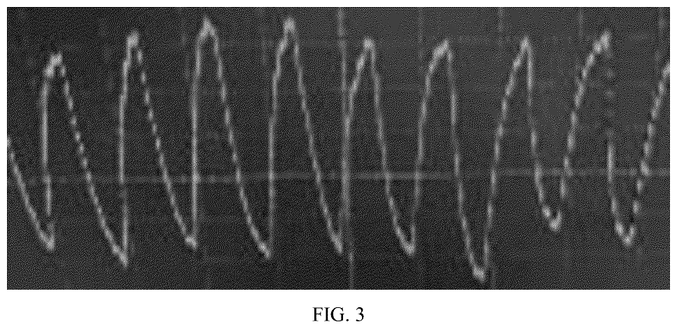

### REFERENCE NUMERALS IN FIGURES

101—first metal layer; 102—reflective layer; 103—first dielectric layer; 104—phase change layer; 105—second dielectric layer; 106—second metal layer; 107—third dielectric layer; and 108—lithium tantalate single-crystal wafer structure.

### DETAILED DESCRIPTION OF THE EMBODIMENTS

In order to make the objectives, technical solutions and advantages of the present disclosure clearer, the technical solutions in the present disclosure will be clearly and completely described below in combination with the accompanying drawings in the present disclosure. Apparently, the examples described are merely some rather than all of the examples of the present disclosure. Based on the described examples of the present disclosure, all other examples acquired by those of ordinary skill in the art without making creative efforts fall within the protection scope of the present disclosure.

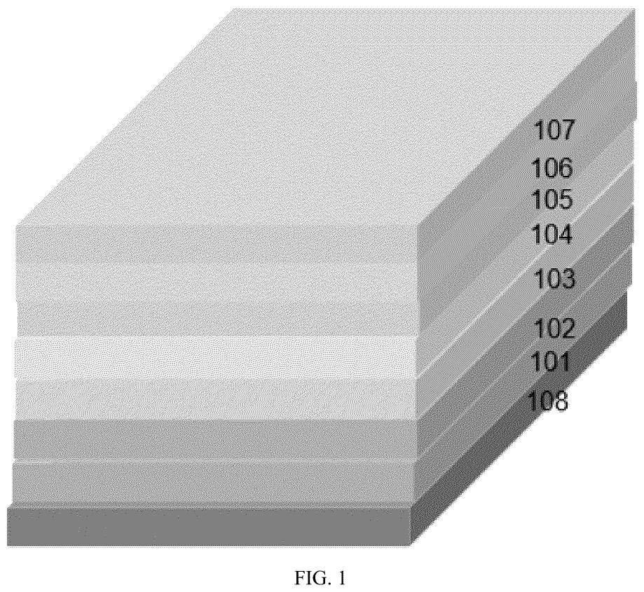

With reference to FIG. 1, a narrowband light absorption device based on a phase change material described in the present disclosure includes:
a narrowband light absorption cavity structure, including a metal layer, a dielectric layer, and a phase change layer;
a lithium tantalate single-crystal wafer structure 108, disposed below the narrowband light absorption cavity structure; and
when light irradiates the narrowband light absorption cavity structure, the narrowband light absorption cavity structure is configured to absorb light of a corresponding wavelength to produce a pyroelectric effect, and the lithium tantalate single-crystal wafer structure is configured to generate current so as to obtain light intensity information of the light according to a magnitude of the current, and change a state of the phase change layer according to the magnitude of the current to control an on-off state of the switch.

In this example, the number and arrangement order of the metal layer, the dielectric layer, and the phase change layer are not limited. Optionally, a plurality of the metal layers are disposed on both sides of the phase change layer, and a plurality of the dielectric layers are disposed on both sides of the phase change layer to form a Fabry-perot (FP) cavity structure.

The phase change layer includes a phase change material, and the metal layers on both sides of the phase change material not only form the FP cavity with the phase change material, but also control the phase change of the phase change material. When a voltage is applied to the metal layers on both sides of the phase change material, a crystal structure of the phase change material may be changed, such that an absorption peak and position of the narrowband light absorption cavity structure are adjusted.

When the narrowband light absorption cavity structure is combined with the lithium tantalate single-crystal wafer structure 108, light irradiates the narrowband light absorption cavity structure, and light of a corresponding wavelength is absorbed. Due to the pyroelectric effect, the lithium tantalate single-crystal wafer structure 108 generates current, and the light intensity information is obtained according to the magnitude of the current. Additionally, a state of the phase change material may be changed according to the magnitude of the current to achieve an effect of switching on and off, and an on-off state of the switch is controlled according to actual needs.

The phase change material may be regulated based on the magnitude of current output by the lithium tantalate single-crystal wafer structure 108. The magnitude of the current output by the lithium tantalate single-crystal wafer structure 108 may be compared with a magnitude of current required for switching on or off, and a voltage or pulse current applied to the phase change material may be adjusted according to comparison results, such that the magnitude of the current output by the lithium tantalate single-crystal wafer structure 108 is consistent with the magnitude of the current required for switching on or off.

Through this design, the narrowband light absorption cavity structure may be adjusted according to actual needs, a target light absorption ratio may be adjusted, a switching ratio reaches up to more than 90%, and insensitivity to incident light angle variations meets operational requirements of a narrowband absorber in a sensor or a monochromatic light detector.

In this example, the narrowband light absorption cavity structure absorbs a corresponding wavelength, and due to the pyroelectric effect, the lithium tantalate single-crystal wafer structure generates current, the light intensity information is obtained according to the magnitude of the current, to monitor the light intensity; and the state of the phase change layer is changed according to the magnitude of the current, the target light absorption ratio is adjusted, dynamic switching control is achieved, and the narrowband light absorption cavity structure features a very narrow full width at half maximum (FWHM), insensitivity to incident light angle variations, a simple structure, easy integration, and a high switching ratio.

On the basis of the above example, the narrowband light absorption cavity structure in this example includes a first metal layer 101, a first dielectric layer 103, a phase change layer 104, a second dielectric layer 105, a second metal layer 106, and a third dielectric layer 107 arranged sequentially from bottom to top.

The narrowband light absorption cavity structure is composed of a dielectric-metal-dielectric-phase change material-dielectric-metal cavity or a plurality of cavities of the same type. The third dielectric layer 107 at a top thereof is a lossless material covering layer.

On the basis of the above example, in this example, the voltage applied to the first metal layer is regulated according to the magnitude of the current to control a crystallization-amorphization ratio of the phase change material in the phase change layer so as to regulate the absorption of the light.

The phase change material of the phase change layer 104 may switch between a crystalline state and an amorphous state under electrical stimulation or laser stimulation conditions, causing changes in the transmittance and reflectance of the phase change layer. A transparent lossless material MgF₂ is deposited under the third dielectric layer 107 at the top thereof, and the phase change layer 104 may control a crystallization state of the phase change material by applying a voltage to the first metal layer 101 made of tungsten (W).

Specifically, when a medium-intensity pulse voltage is applied to W, W generates heat, the phase change material, under the thermal action, is heated to a temperature above a crystallization temperature and below a melting temperature, the temperature is maintained for a certain period of time, and in this case, crystal lattices are orderly arranged to form a crystalline state, with transition from the amorphous state to the crystalline state.

When a short and strong voltage is applied to W, high heat is generated instantaneously, such that the temperature of the phase change material rises above the melting temperature, and a long-range order of the crystalline state is destroyed. A very short pulse falling edge causes the phase change material to be quickly cooled to below the crystallization temperature, such that the phase change material maintains the amorphous state, with the transition from the crystalline state to the amorphous state.

The ratio of light absorption by the narrowband light absorption cavity structure is regulated based on the changes in transmittance and reflectance of the phase change material of the phase change layer 104 during transition between the amorphous state and the crystalline state.

The phase change material of the phase change layer 104 may include the following chalcogenide compounds and their alloys, including but not limited to GST, Germanium-Sb-Selenium-Tellurium (GSST), IST, GeSbTe, AgInSbTe, InSbTe, AgSbTe, Ag₂In₄Sb₇₆Te₁₇ (AIST) and other high-loss and low-refractive-index phase change materials. Additionally, atomic percentages in the above chemical formulas are variable. The phase change material layer may further include at least one dopant, such as carbon (C) or nitrogen (N). Preferably, GSST is selected as the phase change material, which has a high loss, a low refractive index, and good thermal stability in a visible light range.

The phase change layer of the narrowband light absorption cavity structure shows significant differences in light absorption in different states, and the phase change material exhibits stable performance in the crystalline state and the amorphous state, such that the voltage or laser may be removed when the phase change material is in a stable state. The power consumption of an entire detection device during the detection process is very low and is dynamically adjustable.

On the basis of the above example, the phase change material of the phase change layer used in this example has an optical loss greater than a first preset threshold, and a refractive index less than a second preset threshold; and
the reflectance of the metal layer is greater than a third preset threshold.

The phase change material of the narrowband light absorption cavity structure may be GSST, and the metal may be silver (Ag). GSST is an ultra-thin phase change material with a strong optical loss, and Ag is a high-reflectance metal material. The phase change material in the narrowband light absorption cavity structure has the high loss and low refractive index, including but not limited to GSST, and any other material with such characteristics formed by doping.

The narrowband light absorption cavity structure is composed of a high-loss and low-refractive-index phase change material and a metal material. An ultra-thin phase change material film with the strong optical loss and low refractive index is deposited on a highly reflective metal substrate.

A lithium tantalate single-crystal wafer is bonded to a bottom of the structure, selectively absorbed light is converted into thermal energy and conducted to a pyroelectric material, and the pyroelectric material converts the thermal energy into electric energy through the pyroelectric effect. Therefore, an intensity of light signals may be detected according to the magnitude of the current, a voltage applied to a metal driving the phase change material may be adjusted, and the crystallization-amorphization ratio of the phase change material is adjusted to control the absorption of light. Compared with traditional narrowband light absorption cavity structures, this design enables to monitor the intensity of the target light and achieve dynamic switching control, and features the simple structure and easy integration.

On the basis of the above example, the phase change material of the phase change layer 104 used in this example has a thickness of less than 1 μm.

The phase change material of the phase change layer 104 used in this example has a thickness of less than 1 μm, and since an increase in the thickness of the phase change material leads to a rising temperature required for the crystallization of the phase change material, a relatively appropriate thickness is within 1 μm. The phase change material of the phase change layer 104 may be driven by voltage. During voltage driving, a voltage is applied to the metal W at a bottom of the narrowband light absorption cavity structure to cause phase change of the phase change material.

In this example based on the above examples, a plurality of the phase change layers 104 are arranged, and each of the phase change layers 104 includes a phase change material layer and electrode layers disposed on both sides of the phase change material layer.

In this example based on the above examples, the electrode layer between two adjacent phase change material layers is shared.

In this example based on the above examples, as shown in FIG. 1, a reflective layer 102 is further arranged between the first metal layer 101 and the first dielectric layer 103.

In this example based on the above examples, the first metal layer 101 is made of W, the reflective layer 102 is made of Ag, the first dielectric layer 103 is made of titanium dioxide (TiO₂), the phase change layer 104 is made of GSST, the second dielectric layer 105 is made of TiO₂, the second metal layer 106 is made of Ag, and the third dielectric layer 107 is made of magnesium fluoride (MgF₂).

In this example based on the above examples, the first metal layer 101 has a thickness of 200 nm, the reflective layer 102 has a thickness of 200 nm, the first dielectric layer 103 has a thickness of 78 nm, the phase change layer 104 has a thickness of 100 nm, the second dielectric layer 105 has a thickness of 78 nm, the second metal layer 106 has a thickness of 22 nm, the third dielectric layer 107 has a thickness of 22 nm, and the lithium tantalate single-crystal wafer structure 108 has a thickness of 75 μm.

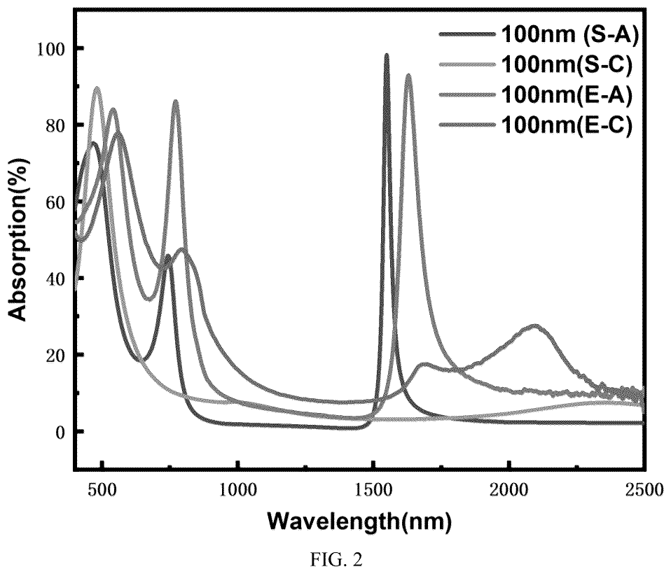

As shown in FIG. 2, by applying different voltages, the phase change material layer changes from the amorphous state to partial crystallization and full crystallization, the magnitude of the applied voltage depends on the magnitude of the current output by the lithium tantalate single-crystal wafer, a corresponding negative feedback is performed until the absorption effect reaches the target effect, and the target light absorption ratio is adjusted according to actual needs.

In this example, a narrowband light absorption cavity structure and a thin film based on a lithium tantalate single-crystal wafer are combined to form an absorption structure detector, which solves the problem that the narrowband light absorption cavity structures of the prior art based on metasurfaces, gratings, and the like fail to adjust the ratio of light absorption at target wavelength bands, are sensitive to incident light angle variations, and have a complex structure. In this example, the thicknesses of the phase change layer, the dielectric layer, and the metal layer, and the state of the phase change layer may be adjusted according to actual application needs to achieve the desired ratio of light absorption in certain wavelength bands, and the tunable narrowband light absorption cavity structure based on the phase change material may be applied to devices such as optical detectors, and has high practicality and broad application prospects.

Finally, it should be noted that the above examples are merely intended to illustrate the technical solution of the present disclosure, but not to limit the same; although the present disclosure has been described in detail with reference to the foregoing examples, it should be understood by those of ordinary skill in the art that the technical solutions described in the foregoing examples may be modified or equivalents may be substituted for some of the technical features thereof; and the modification or substitution does not make the essence of the corresponding technical solution deviate from the spirit and the scope of the technical solution of each example of the present disclosure.

What is claimed is:

1. A narrowband light absorption device based on a phase change material, comprising:
a narrowband light absorption cavity structure, comprising a metal layer, a dielectric layer, and a phase change layer;
a lithium tantalate single-crystal wafer structure, being disposed below the narrowband light absorption cavity structure; and
when light irradiates the narrowband light absorption cavity structure, the narrowband light absorption cavity structure is configured to absorb light of a corresponding wavelength to produce a pyroelectric effect, and the lithium tantalate single-crystal wafer structure is configured to generate current so as to obtain light intensity information of the light according to a magnitude of the current, and change a state of the phase change layer according to the magnitude of the current to control an on-off state of the switch.

2. The narrowband light absorption device based on a phase change material according to claim 1, wherein the narrowband light absorption cavity structure comprises a first metal layer, a first dielectric layer, a phase change layer, a second dielectric layer, a second metal layer, and a third dielectric layer arranged sequentially from bottom to top.

3. The narrowband light absorption device based on a phase change material according to claim 2, wherein a voltage applied to the first metal layer is regulated according to the magnitude of the current to control a crystallization-amorphization ratio of the phase change material in the phase change layer so as to regulate the absorption of the light.

4. The narrowband light absorption device based on a phase change material according to claim 1, wherein the phase change material of the phase change layer used has an optical loss greater than a first preset threshold, and a refractive index less than a second preset threshold; and
reflectance of the metal layer is greater than a third preset threshold.

5. The narrowband light absorption device based on a phase change material according to claim 1, wherein the phase change material of the phase change layer used has a thickness of less than 1 μm.

6. The narrowband light absorption device based on a phase change material according to claim 1, wherein a plurality of the phase change layers are arranged, and each of the phase change layers comprises a phase change material layer and electrode layers disposed on both sides of the phase change material layer.

7. The narrowband light absorption device based on a phase change material according to claim 6, wherein the electrode layer between two adjacent phase change material layers is shared.

8. The narrowband light absorption device based on a phase change material according to claim 2, wherein a reflective layer is further arranged between the first metal layer and the first dielectric layer.

9. The narrowband light absorption device based on a phase change material according to claim 8, wherein the first metal layer is made of tungsten (W), the reflective layer is made of silver (Ag), the first dielectric layer is made of titanium dioxide (TiO₂), the phase change layer is made of Germanium-Sb-Selenium-Tellurium (GSST), the second dielectric layer is made of TiO₂, the second metal layer is made of Ag, and the third dielectric layer is made of magnesium fluoride (MgF₂).

10. The narrowband light absorption device based on a phase change material according to claim 9, wherein the first metal layer has a thickness of 200 nm, the reflective layer has a thickness of 200 nm, the first dielectric layer has a thickness of 78 nm, the phase change layer has a thickness of 100 nm, the second dielectric layer has a thickness of 78 nm, the second metal layer has a thickness of 22 nm, the third dielectric layer has a thickness of 22 nm, and the lithium tantalate single-crystal wafer structure has a thickness of 75 μm.
